(19) United States
(12) Patent Application Publication
(10) Pub. No.: US 2010/0052175 A1
(43) Pub. Date: Mar. 4, 2010

(54) REDUCING LEAKAGE AND DIELECTRIC BREAKDOWN IN DIELECTRIC MATERIALS OF METALLIZATION SYSTEMS OF SEMICONDUCTOR DEVICES BY FORMING RECESSES

(76) Inventors: Robert Seidel, Dresden (DE); Ralf Richter, Dresden (DE)

Correspondence Address: WILLIAMS, MORGAN & AMERSON, 10333 RICHMOND, SUITE 1100, HOUSTON, TX, 77042, US

(21) Appl. No.: 12/507,421

(22) Filed: Jul. 22, 2009

(30) Foreign Application Priority Data
Aug. 29, 2008 (DE) 10 2008 044 964.4

(51) Int. Cl. H01L 23/48; H01L 21/768

(52) U.S. Cl. 257/762; 438/653; 438/675; 257/E21.584; 257/E21.576; 257/E23.011

(57) ABSTRACT

By recessing metal lines and/or the dielectric material of a metallization layer of sophisticated semiconductor devices, the time to dielectric breakdown may be increased due to reducing electrical fields and diffusion paths at the top of the metal lines.

### BACKGROUND OF THE INVENTION

1. Field of the Invention

Generally, the present disclosure relates to microstructures, such as advanced integrated circuits, and, more particularly, to the formation of conductive structures, such as copper-based metallization layers.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption and/or diversity of functions. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area as typically the number of interconnections required increases more rapidly than the number of circuit elements. Thus, usually a plurality of stacked “wiring” layers, also referred to as metallization layers, is provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, memory chips, ASICs (application specific ICs) and the like.

Advanced integrated circuits, including transistor elements having a critical dimension of 0.05 μm and even less, may, therefore, typically be operated at significantly increased current densities of up to several kA per cm² in the individual interconnect structures, despite the provision of a relatively large number of metallization layers, owing to the significant number of circuit elements per unit area. Consequently, well-established materials, such as aluminum, are being replaced by copper and copper alloys, a material with significantly lower electrical resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials, which are typically used in combination with copper in order to reduce the parasitic capacitance within complex metallization layers. In order to provide the necessary adhesion and to avoid the undesired diffusion of copper atoms into sensitive device regions, it is, therefore, usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitance of neighboring copper lines, which may result in non-tolerable signal propagation delays. Hence, a thin conductive barrier layer that also imparts the required mechanical stability to the copper is usually formed so as to separate the bulk copper from the surrounding dielectric material, thereby reducing copper diffusion into the dielectric materials and also reducing the diffusion of unwanted species, such as oxygen, fluorine and the like, into the copper. Furthermore, the conductive barrier layers may also provide highly stable interfaces with the copper, thereby reducing the probability for significant material transport at the interface, which is typically a critical region in view of increased diffusion paths that may facilitate current-induced material diffusion. Currently, tantalum, titanium, tungsten and their compounds, with nitrogen and silicon and the like, are preferred candidates for a conductive barrier layer, wherein the barrier layer may comprise two or more sub-layers of different composition to meet the requirements in terms of diffusion suppressing and adhesion properties.

Another characteristic of copper significantly distinguishing it from aluminum is the fact that copper may not be readily deposited in larger amounts by chemical and physical vapor deposition techniques, thereby requiring a process strategy that is commonly referred to as the damascene or inlaid technique. In the damascene process, first, a dielectric layer is formed which is then patterned to include trenches and/or vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less, in combination with trenches having a width ranging from 0.1 μm to several μm. Electrochemical deposition processes for copper are well established in the field of electronic circuit board fabrication. However, for the dimensions of the metal regions in semiconductor devices, the void-free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure to insure both high yield and the required product reliability. In particular, it is important to identify, monitor and reduce degradation and failure mechanisms in interconnect structures for various configurations to maintain device reliability for every new device generation or technology node.

Accordingly, a great deal of effort has been made in investigating the degradation of copper interconnects, especially in combination with low-k dielectric materials having a relative permittivity of 3.0 or even less, in order to find new materials and process strategies for forming copper-based lines and vias with a low overall permittivity.

One failure mechanism, which is believed to significantly contribute to a premature device failure, is the electromigration-induced material transport, particularly along an interface formed between the copper and a dielectric cap layer, which may be provided after filling in the copper material in the trenches and via openings, the side walls of which are coated by the conductive barrier materials. In addition to maintaining copper integrity, the dielectric cap layer may usually act as an etch stop layer during the formation of the via openings in the interlayer dielectric. Frequently used materials are, for example, silicon nitride and silicon carbon nitride, which exhibit a moderately high etch selectivity to typically employed interlayer dielectrics, such as a plurality of low-k dielectric materials, and also suppress the diffusion of copper onto the interlayer dielectric. Recent research results seem to indicate, however, that the interface formed between the copper and dielectric cap layer is a major diffusion path for material transport during operation of the metal interconnect.

Consequently, a plurality of alternatives have been developed in an attempt to enhance the interface characteristics between the copper and the cap layer having the capability of reliably confining the copper and maintaining its integrity. For example, it has been proposed to selectively provide conductive materials on top of the copper-containing region, which may exhibit superior electromigration performance while not unduly reducing the overall resistance of the corresponding metal line. For instance, various alloys, such as a compound of cobalt/tungsten/phosphorous (CoWP), a compound of nickel/molybdenum/phosphorous (NiMoP) and the like, have proven to be promising candidates for conductive cap layers, which may significantly reduce electromigration effects within a corresponding metal line. Although these compounds provide superior electromigration performance and may be implemented into the overall process flow for manufacturing complex metallization systems, since these compounds may be efficiently deposited on the basis of selective electrochemical deposition recipes, it turns out, however, that severe defects may be observed in metallization systems including copper lines with a conductive cap layer. For example, increased leakage currents and dielectric breakdown may occur in such devices compared to devices having a metallization system based on a dielectric cap layer.

In addition, during operation of the device, a reduced time to dielectric breakdown may be observed in sophisticated metallization systems, wherein it is believed that a dominant source of the premature dielectric breakdown may represent the interface between the dielectric materials of two subsequent metallization layers in closely spaced metal lines, as will be explained with reference to FIG. 1.

FIG. 1 schematically illustrates a cross-sectional view of a semiconductor device 100 comprising a substrate 101, in and above which may be formed circuit elements, such as transistors and the like, as required by the overall circuit configuration of the semiconductor device 100. As previously indicated, the continuous shrinkage of the critical feature sizes, which may currently be at approximately 50 nm and less, requires a corresponding adaptation of the feature sizes of metal lines and vias in a metallization system 130 of the device 100. In the example shown in FIG. 1, the metallization system 130 may comprise a metallization layer 110 in a substantially complete state and a metallization layer 120 prior to patterning the corresponding dielectric material contained therein. The metallization layer 110 may comprise a dielectric material 111, such as a low-k dielectric material, and a plurality of metal lines 112, which may typically include a highly conductive metal 112A, such as copper, in combination with a conductive barrier material 112B, such as tantalum, tantalum nitride and the like. Furthermore, with respect to enhanced copper confinement and electromigration behavior, frequently, a conductive cap layer 113 may be formed on a top surface 112S of the metal region 112. As previously explained, a plurality of alloys may be used, which may have a moderately low resistivity, while at the same time providing a strong interface with the surface 112S, which may therefore result in a reduced degree of current-induced material diffusion, as explained above. Typically, the metal lines 112 have a certain degree of tapering so that the critical dimension in the vicinity of the top surface 112S may be greater compared to the corresponding critical width at the bottom of the metal lines 112. Consequently, the distance between neighboring closely spaced metal lines 112D is shortest at an interface 111S of the dielectric material 111 with a subsequent dielectric material 122, which may be considered as a dielectric material of the subsequent metallization layer 120 or which may be considered as a cap or cover layer of the dielectric material 111. At any rate, the dielectric materials 122, 111 may typically differ in material composition so that diffusion paths for any contaminants, such as metal residues and the like, may preferably take place at the interface 111S. Furthermore, a further dielectric material 121, such as a low-k dielectric material and the like, may be formed on the dielectric layer 122.

Typically, the semiconductor device 100 as shown in FIG. 1 may be formed on the basis of the following process techniques. After fabricating any circuit elements in and above the substrate 101 based on well-established techniques according to specific design rules, which may require critical dimensions of 50 nm and significantly less for circuit elements, such as transistors and the like, an appropriate contact structure (not shown) may be formed so as to connect the corresponding circuit elements with the metallization system 130. Thereafter, the metallization system 130 may be formed, wherein the number and the configuration of the individual metallization layers 110, 120 may depend on the complexity and design criteria of the circuit provided by the circuit elements in the device level, as previously explained. For example, the metallization layer 110 including the metal lines 112 may be formed by depositing the dielectric material 111, which may represent a material of reduced permittivity, by any appropriate deposition technique, such as plasma enhanced chemical vapor deposition (CVD), spin-on techniques and the like. Thereafter, an appropriate etch mask may be formed on the basis of lithography, wherein hard mask materials may be used, if required, in order to define the lateral dimension 111S and the spacing 112D between adjacent metal lines 112. Thereafter, an anisotropic etch process may be performed on the basis of well-established recipes, during which a certain degree of tapering may be created so that typically the width 112W and the spacing 112D may have to be selected as large as is compatible with the overall design rules for a given high density of the metal lines 112. After the etch process and removal of the corresponding etch mask, the barrier material 112B may be formed, for instance, by sputter deposition and the like, followed by the filling in of the copper material, which may typically be accomplished by electrochemical deposition techniques. Thereafter, excess material of the copper fill material and of the conductive barrier layer 112B may be removed, wherein, typically, chemical mechanical polishing (CMP) techniques may be used. Consequently, during a final phase of a corresponding polishing sequence, copper material, barrier material and material of the dielectric layer 111 may be exposed to the polishing ambient, which may result in a certain degree of “copper contamination” of the surface 111S of the dielectric material 111. Although highly efficient cleaning processes may be performed in a later manufacturing stage, nevertheless, the presence of even minute copper residues may contribute to a reduced dielectric strength, in particular at the interface 111S, at which also the distance between neighboring metal lines 112 may be shortest. The situation may even become more critical in semiconductor devices in which the metal-containing cap material 113 may be provided. For this purpose, typically, a further electrochemical deposition process, frequently an electroless process, may be performed to selectively deposit the desired conductive cap material 113 on the surface portions 112S. During this process, exposed surface areas of the dielectric material 111 may also come into contact with electrolyte solutions comprising metal atoms which may also diffuse into the dielectric material to a certain degree. Thus, cleaning processes may be performed after the electroless deposition process to remove contaminants, wherein, however, minute metal residues may still remain from preceding chemical mechanical polishing of the copper material and the subsequent electroless deposition of the conductive cap material 113. Thereafter, the dielectric material 122 may be deposited, for instance, by plasma enhanced CVD techniques, wherein the material 122 may act as an etch stop material during the patterning of the dielectric material 121 of the metallization layer 120. For example, silicon carbide, nitrogen-containing silicon carbide and the like may frequently be used as appropriate etch stop materials. However, due to a specific mismatch in material composition and molecular structure between the materials 122 and the dielectric material 111, the interface 111S may represent a diffusion path for metal residues which may result in an even further reduced dielectric strength upon operating the device 100, in which typically repeatedly moderately high temperatures may be created within the metallization system 130.

The dielectric material 121 may be deposited and may subsequently be patterned by using the layer 122 as a stop material, wherein subsequently vias and metal lines may be formed in the metallization layer 120.

Thus, the close proximity of the metal lines 112, in particular at the interface 111S, may provide increased electrical fields upon operation of the device 100, which may even become more critical due to the less stable interface 111S and the presence of even minute metal residues, for instance in the form of copper or material of the conductive cap layer 113. Therefore, premature failure, that is, dielectric breakdown, may be observed in metallization levels of critical semiconductor devices.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques and semiconductor devices in order to enhance the dielectric characteristics, i.e., the behavior with respect to the response of dielectric materials to applied voltages and with respect to reducing parasitic leakage currents in the dielectric material of metallization systems by recessing a metal region and/or the dielectric material in order to provide enhanced interface characteristics of the dielectric material between closely spaced metal lines. For instance, recessing the metal region prior to actually forming a cap layer, such as a conductive cap layer or a dielectric cap layer, may provide enhanced surface condition for the subsequent deposition process and may also remove contaminants from exposed surface areas of the dielectric material, thereby enhancing the overall reliability of the dielectric material. In other cases, in addition to or alternatively, the dielectric material may be recessed, for instance, after forming a conductive cap layer, thereby efficiently removing any metal residues, thereby also contributing to enhanced dielectric characteristics at the top of the corresponding metallization level. Thus, time to dielectric breakdown may be increased for given design rules of a metallization system under consideration compared to conventional strategies.

One illustrative method disclosed herein comprises removing material of a copper-containing metal region formed in a low-k dielectric material of a metallization layer of a semiconductor device by performing a selective etch process to form a recess. Furthermore, the method comprises forming a cap material at least in the recess of the metal region.

A further illustrative method disclosed herein comprises removing a portion of a dielectric material selectively to metal regions formed in the dielectric material so as to form recesses in the dielectric material with respect to the metal regions, wherein the dielectric material and the metal regions represent a portion of a metallization layer for semiconductor devices. Additionally, the method comprises forming a cap material at least on the metal regions.

One illustrative semiconductor device disclosed herein comprises a first dielectric material formed above a substrate and copper-containing metal regions formed in the first dielectric material, wherein the copper-containing metal regions have sidewall portions and a top surface. The top surface is recessed with respect to a top surface of the first dielectric material. Furthermore, a second dielectric material is formed on the first dielectric material and above the top surface. Finally, a conductive cap layer is formed on the top surface of the copper-containing metal regions.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a conventional semiconductor device when forming a sophisticated metallization system;

FIGS. 2a-2e schematically illustrate cross-sectional views of a semiconductor device during various manufacturing stages in forming a metallization layer by recessing the metal lines thereof, according to illustrative embodiments;

FIG. 2f schematically illustrates the semiconductor device according to further illustrative embodiments in which sidewall spacers may be formed within recesses of the metal regions;

FIG. 2g schematically illustrates the semiconductor device according to still a further illustrative embodiment in which, after forming a conductive cap material on the previously recessed metal region, material of the dielectric layer may be removed; and

FIGS. 2h-2i schematically illustrate cross-sectional views of the semiconductor device during various manufacturing stages, in which a conductive cap layer may be formed on the metal lines with a subsequent recessing of the dielectric material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to techniques and semiconductor devices in which the dielectric strength of dielectric materials, such as low-k dielectric materials, which are to be understood as dielectric materials having a dielectric constant of 3.0 and less, may be enhanced in view of the electrochemical deposition of a metal, such as copper, a conductive cap material and the like and the corresponding manufacturing sequence associated therewith by providing conditions for reducing electrical field in particular at the top of the corresponding metal lines and/or by reducing the probability of metal diffusion at an interface between two adjacent dielectric materials. For this purpose, the metal of the metal line may be recessed and/or the dielectric material may be recessed so as to efficiently reduce the probability of metal diffusion and enhancing process conditions during the further processing. In some illustrative embodiments, both mechanisms may be combined to provide enhanced confinement of a conductive cap material, which may be formed within a recess of the previously generated metal line, wherein a subsequent recessing of the surrounding dielectric material may efficiently remove any additional metal contaminants. In still other cases, the recessing of the metal region may be accompanied by the formation of diffusion hindering sidewall spacers, which may contribute to enhanced dielectric strength and metal confinement. Consequently, for given design rules and a given configuration of the metallization system of an advanced semiconductor device, superior reliability, for instance with respect to time to dielectric breakdown, may be obtained, while not unduly contributing to overall process complexity. In some illustrative embodiments, even an enhanced surface topography may be accomplished by appropriately recessing the metal regions prior to providing the conductive cap material, while, in other cases, a portion of the dielectric material may be replaced after forming a conductive cap material, thereby providing a reduced degree of metal contamination in enhanced overall surface topography.

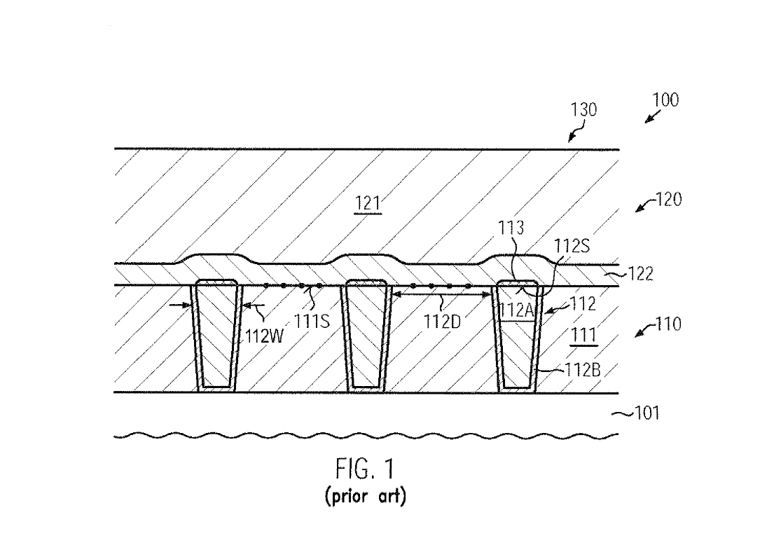

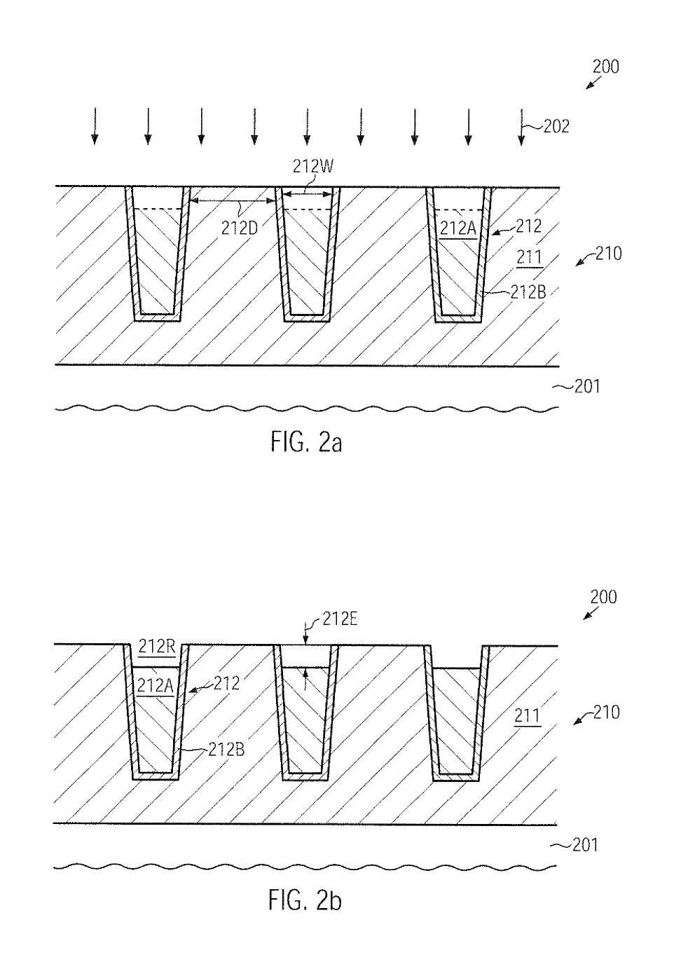

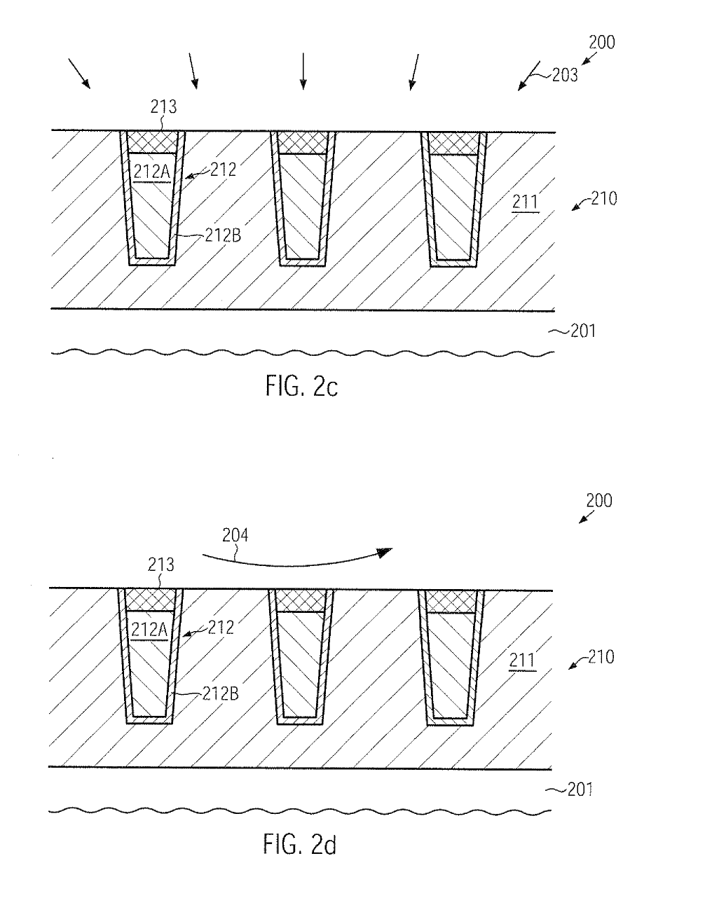

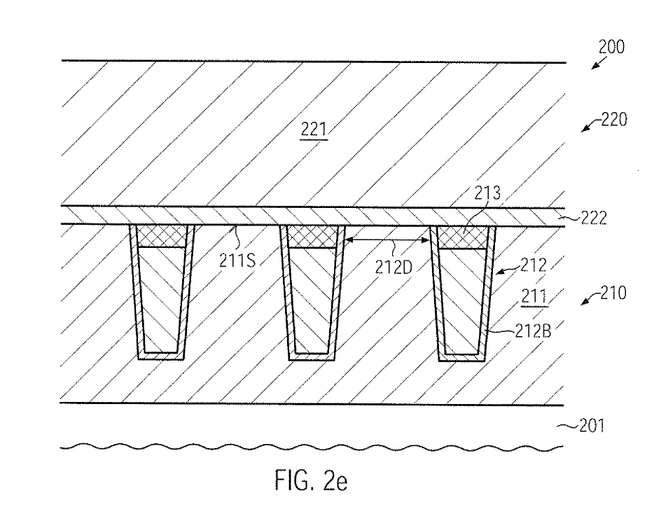

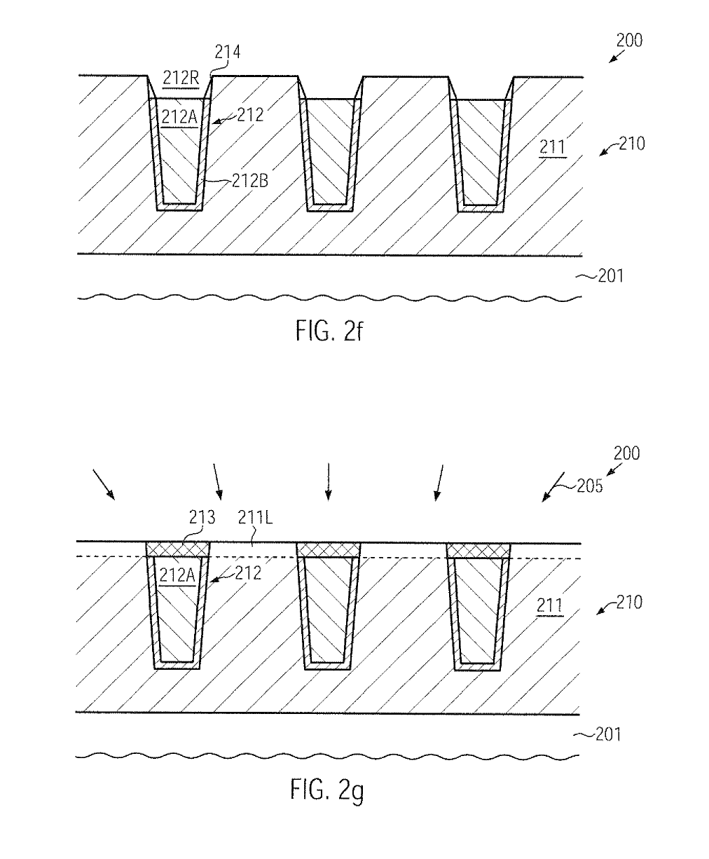

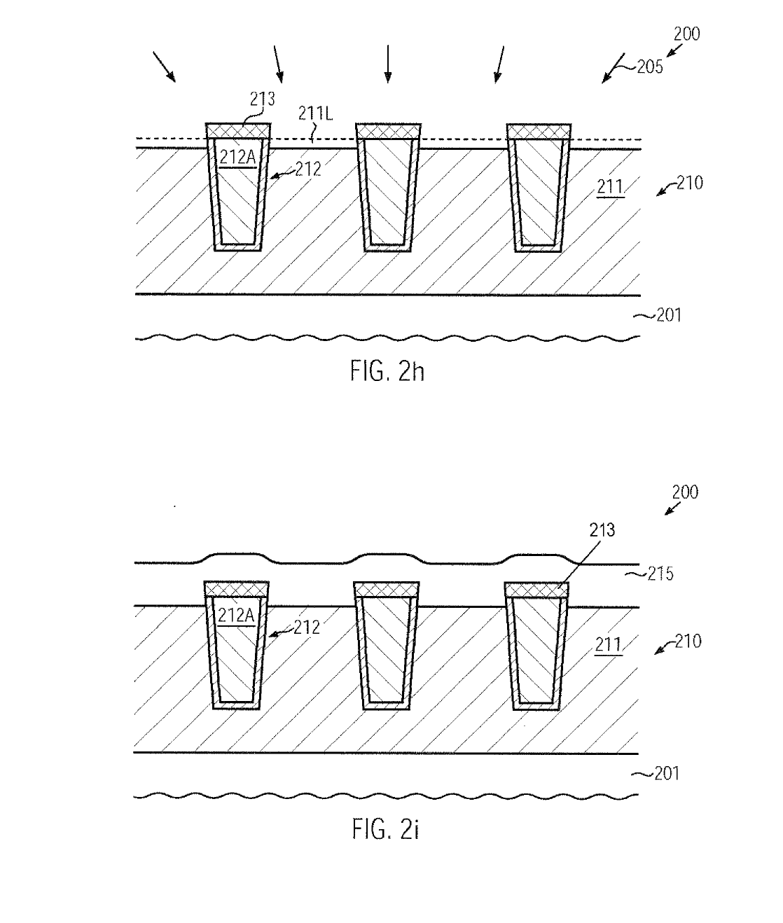

With reference to FIGS. 2a-2i, further illustrative embodiments will now be described in more detail wherein reference is also made to FIG. 1 if appropriate.

FIG. 2a schematically illustrate a cross-sectional view of a semiconductor device 200, which may comprise a substrate 201 and at least one metallization layer 210 formed above the substrate 201. The substrate 201 may represent any appropriate carrier material for forming thereabove the metallization layer 210. For example, the substrate 201 may also comprise a device level in and above which circuit elements, such as transistors, capacitors, resistors and the like, may be provided, the electrical connection of which may be established at least in part by the one or more metallization layers 210. Moreover, with respect to other characteristics of the substrate 201, it may also be referred to the semiconductor device 100 as described with reference to FIG. 1. The metallization layer 210 may represent any level of a more or less complex metallization system, wherein, in some illustrative embodiments, the metallization layer 210 may represent a wiring level of an advanced semiconductor device in which a dielectric material 211 of the layer 210 may be provided, at least partially, in the form of a low-k dielectric material. That is, the dielectric material 211 may comprise material of a dielectric constant of 3.0 or less, such as 2.5 or less, if so-called ultra low-k dielectric materials are considered. It should be appreciated that the dielectric material 211 may also comprise other dielectrics, such as silicon dioxide, silicon nitride, silicon carbide, nitrogen-enriched silicon carbide and the like, in order to provide the desired overall characteristics. The metallization layer 210 may comprise a plurality of metal lines 212 possibly in combination with vias (not shown), which may provide a connection to a lower lying metallization layer (not shown). In other cases, the metal lines 212 may connect to a contact structure (not shown) which in turn may present a vertical contact structure for connecting to contact areas of semiconductor elements, such as drain and source regions of field effect transistors, gate electrode structures and the like. The metal lines 212 may have a lateral size and depth in accordance with the overall design rules for the metallization layer 210 under consideration. For example, a minimum design distance 212D between adjacent two of the metal lines 212 at the top of the metal lines 212 may be 100 nm and less, such as approximately 60 nm and less for highly sophisticated semiconductor devices. Similarly, a width 212W at the top of the lines 212 may range from several μm to a hundred μm and less, depending on the metallization level under consideration and the overall design rules of the device 200. On the other hand, a depth of the metal lines 212 may be several hundred nm to several μm, depending on the metallization level under consideration. The metal lines 212 may comprise a conductive barrier material 212B and a highly conductive metal 212A, such as copper, copper alloys, silver and the like.

The semiconductor device 200 as shown in FIG. 2a may be formed on the basis of similar process techniques as are also described with reference to the semiconductor device 100 when referring to the formation of the metal lines 112. Thus, after a deposition of the conductive barrier material 212B and the filling in of the metal 212A, any excess material may be removed, as also previously explained. However, contrary to the conventional approaches, the semiconductor device 200 may be exposed to an etch ambient 202 in order to remove a portion of at least the metal 212A selectively with respect to the dielectric material 211. For this purpose, the etch ambient 202 may be established on the basis of appropriate wet chemical recipes or plasma assisted chemistries. For example, copper material may be etched by a plurality of wet chemical etch techniques selectively with respect to a plurality of dielectric materials, such as chloride-based chemistries and the like, for which a plurality of well-established etch recipes are available from the printed wiring board technology. In other cases, surface portions of the material 212A may be oxidized and subsequently the oxidized portions may be removed by wet chemical or plasma assisted etch techniques. In some illustrative embodiments, a CMP stop layer (not shown) may be formed on top of the dielectric material 211 after the deposition of the material 211 and prior to the patterning thereof, wherein at least a portion of the corresponding stop layer may be maintained to provide enhanced integrity during the etch process 202, when a direct contact of a sensitive dielectric material, such as a ULK material and the like, to the etch ambient 202 is considered inappropriate. The material removal during the process 202 may readily be established by determining a removal rate for a given etch chemistry and a known composition of the metal 212A.

FIG. 2b schematically illustrates the semiconductor device 200 after completing the etch process 202 of FIG. 2a. As illustrated, recesses 212R are formed in the metal lines 212, wherein a depth of the recesses 212R, indicated as 212E, may be adjusted on the basis of the etch parameters, as described above. For instance, the depth 212E may be selected to be approximately 20-50 nm or more, depending on a desired thickness of a further cap material still to be formed and on the desired surface topography that may result from the subsequent deposition of the cap material. For instance, in some illustrative embodiments, the recesses 212R may be formed with an appropriate depth that may substantially correspond to a desired thickness of a conductive cap material to be formed in a subsequent manufacturing stage. In some illustrative embodiments, the further processing may be continued by depositing an appropriate dielectric cap material, such as nitrogen-containing silicon carbide and the like, if a conductive cap material may be considered inappropriate. In this case, the dielectric cap material may be deposited so as to fill the recesses 212R, wherein a subsequent planarization process may be performed in order to reduce a thickness of the dielectric barrier material outside of the metal lines 212, while nevertheless providing a sufficient thickness for reliably confining the material 212A and providing the desired etch stop capabilities during the patterning sequence for forming vias of a subsequent metallization layer. In other embodiments, a corresponding planarization process, for instance a CMP process, may be continued so as to substantially completely remove the corresponding dielectric barrier material from above the dielectric material 211, while in still other cases a portion of the material 211 may be removed so as to efficiently remove any contaminants contained therein, such as copper and the like, thereby providing further enhanced dielectric integrity of the material 211 at the top of the metal lines 212. During the corresponding removal process, the metal 212A may be reliably protected by the dielectric cap material previously formed in the recesses 212R. Thus, even in less sophisticated applications in which a dielectric cap material may be considered appropriate, enhanced overall dielectric characteristics of the metallization layer 210 may be achieved.

FIG. 2c schematically illustrates the semiconductor device 200 during an electrochemical deposition process 203, such as an electroless plating process based on well-established deposition recipes. During the process 203, a conductive cap material 213, such as an appropriate alloy, as previously explained, may be deposited within the recesses 212R of FIG. 2b, thereby providing enhanced confinement of the material 213. It should be appreciated that, in some cases (not shown), the material 213 may be deposited so as to overfill the recesses, while, in other cases, a substantially planar surface topography may be obtained after the deposition process 203. As discussed above with reference to FIG. 2b, in other cases, the deposition process 203 may represent deposition of a dielectric barrier material in combination with an appropriate planarization process, thereby also obtaining a substantially planar surface topography, wherein the corresponding dielectric cap material may or may not cover the dielectric material 211, as previously explained. FIG. 2d schematically illustrates the semiconductor device 200 during a cleaning process 204, which may be based on the application of appropriate wet chemical agents, such as reactive components, de-ionized water and the like, possibly in combination with a mechanical component provided by corresponding brushes and other components which may come into mechanical contact with the exposed surface area of the device 200 during the process 204. Due to the enhanced surface topography after the provision of the conductive cap material 213, enhanced efficiency, in particular of the mechanical component of the cleaning process 204, may be achieved, thereby more efficiently removing any contaminants in the dielectric material 211 between the metal lines 212. Even if the conductive cap material 213 may have been deposited so as to overfill the corresponding recesses, a significantly reduced pronounced surface topography may be obtained for a given desired thickness of the material 213 compared to conventional strategies in which a conductive cap material may be deposited on the metal lines without recessing the same.

FIG. 2e schematically illustrates the semiconductor device 200 in a further advanced manufacturing stage. As illustrated, a further metallization layer 220 may be provided on the metallization layer 210 and may be illustrated in an early manufacturing stage. That is, a dielectric material 222, such as an etch stop material, a “transition” layer with respect to a ULK material and the like, may be formed on the metallization layer 210, thereby forming an interface 211 S with the dielectric material 211 and with the conductive cap layer 213. Furthermore, a dielectric material 221, such as a low-k material, a ULK material and the like, may be formed on the dielectric material 222. Consequently, due to the preceding manufacturing sequence including the formation of the recesses 212R (FIG. 2b), an enhanced dielectric strength at the interface 211S may be obtained due to a reduced metal diffusion or contamination in the preceding manufacturing stages. Furthermore, an enhanced lateral confinement of the conductive cap layer 213 may be accomplished, which may also contribute to a well-defined distance 212D between closely spaced metal lines 212, thereby also reducing the occurring electrical fields during operation of the semiconductor device 200. In other cases, when a dielectric cap material may be formed on the metal lines 212, enhanced conditions with respect to metal contamination may also be achieved at the interface 211S, as is explained above.

FIG. 2f schematically illustrates the semiconductor device 200 according to further illustrative embodiments in which the recesses 212R may be formed as previously described, wherein, however, the conductive barrier material 212B may also be removed within the recesses 212R or wherein the barrier material in the recesses 212R may be considered inappropriate with respect to the diffusion blocking characteristics for copper material due to the previous exposure to a reactive ambient for forming the recesses 212R. In the embodiment shown, sidewall spacers 214 may be formed on sidewalls of the recesses 212R, i.e., spacers 214 may be in contact with the dielectric material 211 when the conductive barrier material 212B may be substantially completely removed during the preceding manufacturing steps, or the spacers 214 may be formed on residues of the material 212B. In the embodiment shown, the conductive barrier material 212B may be completely removed within the recesses 212R and the spacers 214 in the form of a dielectric material, such as silicon dioxide, silicon nitride, nitrogen-containing silicon carbide and the like, may reduce the effective width of the metal region 212 and may provide enhanced diffusion characteristics. The sidewall spacers 214 may be formed by depositing an appropriate material, such as one of the above-specified materials, which may be accomplished on the basis of well-established deposition techniques, such as plasma enhanced CVD and the like, followed by an anisotropic etch process, wherein a pronounced etch selectivity between the material of the spacers 214 and the dielectric material 211 may not be necessary. In other cases, a material may be selected which may be removable with a high degree of selectivity with respect to the material 211. In still other cases, a thin etch stop liner (not shown) may be formed, for instance by deposition, surface treatment and the like, followed by an appropriate spacer material, which may then be etched selectively with respect to the etch stop liner. Thereafter, if desired, the etch stop liner may be removed on the basis of a corresponding wet chemical or plasma assisted etch process. Thereafter, the further processing may be continued, as is for instance described with reference to FIG. 2d, i.e., a conductive cap material may be deposited on the basis of an electrochemical deposition technique.

FIG. 2g schematically illustrates the semiconductor device 200 according to further illustrative embodiments wherein a further etch process 205 may be performed to selectively remove material of the dielectric layer 211 after forming the conductive cap material 213. In this case, any remaining contaminants positioned in a surface layer 21 IL of the dielectric material 211 may be efficiently removed during the process 205, while the cap material 213 may provide the desired integrity of the material 212A. Thus, the dielectric material 211 may be recessed to a certain degree so as to further remove any contaminants contained in the layer 211 L, wherein, however, the resulting surface topography may be comparable to the surface topography of a semiconductor device formed in accordance with conventional strategies, as previously described with reference to FIG. 1, since, due to the preceding recessing of the metal lines 212, a significantly enhanced planar surface topography may be obtained prior to the etch process 205. Consequently, improved conditions during the formation of the conductive cap material 213 may be accomplished by recessing the metal lines 212 as described above, wherein additional superior conditions with respect to metal contamination may be achieved by removing the surface layer 211L. Thereafter, the further processing may be continued, for instance as is described with reference to the device 100.

FIG. 2h schematically illustrates the semiconductor device 200 according to still further illustrative embodiments. As illustrated, the conductive cap layer 213 may be formed on the metal lines 212, which may be accomplished on the basis of process techniques as also described with reference to the device 100. That is, a conductive cap material 213 may be formed so as to extend above the surface layer 211 L of the dielectric material 211, since the metal lines 212 may not be recessed prior to the deposition of the material 213. Thereafter, the device 200 may be exposed to the etch ambient 205 in order to remove the surface layer 211L with a desired thickness, thereby recessing the material 211. It should be appreciated that, in this case, the etch process 205 may be performed in addition to or alternatively to a corresponding cleaning process, such as the process 204 (FIG. 2d), since, by removing the surface layer 211L, corresponding contaminants may also be efficiently removed during the process 205. In this case, the etch process 205 may not negatively contribute to overall cycle time compared to conventional strategies.

FIG. 2i schematically illustrates the semiconductor device 200 in a further advanced manufacturing stage in which a further dielectric material 215 may be formed above the dielectric material 211 and the metal lines 212. In one illustrative embodiment, the material 215 may have a composition comparable or identical to the material 211, which may represent a low-k material, thereby providing a low-k material also immediately adjacent to each of the metal lines 212 and the conductive cap material 213. In this case, a planarization process may be performed, for instance a CMP process, with appropriately set parameters such as downforce and the like in which excess material of the layer 215 may be removed, thereby also planarizing the surface topography, wherein the conductive cap material 213 may act as a CMP stop or control layer, wherein, however, undue metal contamination of the layer 215 may be avoided due to appropriately set CMP parameters. That is, due to the mechanical characteristics of the material 215, a moderately high selectivity between the layer 215 and the conductive cap material 213 may be accomplished during the CMP process, thereby maintaining a moderately low contamination level, which may even further be reduced by a subsequent cleaning process. In still other illustrative embodiments, the further dielectric material 215 may represent an appropriate etch stop or transition material for forming thereon a dielectric material of a subsequent metallization level. In this case, a planarization process may be omitted if the layer thickness as deposited is considered appropriate. In still other illustrative embodiments, the material layer 215 may be planarized to provide a substantially planar surface topography for the subsequent deposition of a further dielectric material, wherein, in some illustrative embodiments, the conductive cap layer 213 may not be exposed so as to avoid undue metal contamination of the planarized layer 215.

Consequently, also in the embodiment shown with reference to FIGS. 2h and 2i, a recessing of the dielectric material 211 may provide enhanced dielectric strength of the layer 211 due to a highly efficient removal of any metal contaminants.

As a result, the present disclosure relates to techniques and semiconductor devices in which sophisticated metallization systems, which may be formed on the basis of low-k dielectrics and copper, exhibit enhanced dielectric strength with respect to time to dielectric breakdown. This may be accomplished by recessing the metal lines and/or the surrounding dielectric material to provide enhanced conditions during the subsequent formation of a dielectric or conductive cap material. In some illustrative embodiments, the recessing of the metal lines may result in an enhanced lateral confinement of a conductive cap material, while enhanced efficiency of a subsequent cleaning process may also be achieved, thereby significantly contributing to enhanced dielectric characteristics of the resulting metallization level.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
removing material of a copper-containing metal region formed in an opening in a low-k dielectric material of a metallization layer of a semiconductor device by performing a selective etch process so as to form a recess above said metal region; and
forming a cap material at least in said recess of said metal region.

2. The method of claim 1, wherein forming said cap material comprises forming a conductive cap layer on said metal region by performing an electrochemical deposition process.

3. The method of claim 1, wherein forming said cap material comprises forming a dielectric material above said metal region so as to confine said copper-containing metal.

4. The method of claim 2, further comprising performing a cleaning process after said electrochemical deposition process.

5. The method of claim 1, further comprising forming a barrier material on sidewalls of said recess.

6. The method of claim 1, wherein said recess has a depth of approximately 20-50 nm.

7. The method of claim 1, further comprising removing material of said dielectric material selectively to said metal region after forming said cap material so as to form second recesses in said dielectric material with respect to said metal region.

8. The method of claim 7, wherein said cap material is provided in the form of a conductive material.

9. The method of claim 7, further comprising forming a dielectric material above said low-k dielectric material and said metal region and planarizing said dielectric material.

10. The method of claim 9, further comprising forming a second low-k dielectric material above said dielectric material and patterning said second low-k dielectric material using said dielectric material as an etch control material.

11. A method, comprising:
forming a plurality of metal regions in a dielectric material;
removing a portion of said dielectric material selectively with respect to said plurality of metal regions so as to form recesses in said dielectric material with respect to said metal regions, said dielectric material and said metal regions representing a portion of a metallization layer of a semiconductor device; and
forming a cap material at least on said metal regions.

12. The method of claim 11, wherein said cap material is formed as a conductive cap material.

13. The method of claim 12, wherein said conductive cap material is formed prior to removing a portion of said dielectric material.

14. The method of claim 12, further comprising forming a metal recess in said metal regions and forming said conductive cap material in said metal recesses.

15. The method of claim 12, further comprising forming a further dielectric material in said recesses and planarizing said further dielectric material prior to forming a subsequent metallization layer.

16. The method of claim 15, wherein said further dielectric material and said dielectric material have substantially the same material composition.

17. The method of claim 11, wherein said dielectric material has a dielectric constant of approximately 3.0 or less.

18. A semiconductor device, comprising:
a first dielectric material formed above a substrate;
copper-containing metal regions formed in said first dielectric material, said copper-containing metal regions having sidewalls and a top surface, said top surface being recessed with respect to a top surface of said first dielectric material; a second dielectric material formed on said first dielectric material and above said top surface; and
a conductive cap layer formed on said top surface of said copper-containing metal regions.

19. The semiconductor device of claim 18, wherein a top surface of said conductive cap layer is positioned at a height level that is approximately equal to or lower than a height level defined by the top surface of said first dielectric material.

20. The semiconductor device of claim 18, wherein the top surface of said copper-containing material is recessed with respect to the top surface of said first dielectric material by approximately 50 nm or more.

21. The semiconductor device of claim 18, wherein a lateral distance of adjacent two of some of said metal regions is approximately 100 nm or less.
